(19) United States
(12) Patent Application Publication
(10) Pub. No.: US 2023/0124666 A1
(43) Pub. Date: Apr. 20, 2023

(54) TWO-AXIS SPIN COATING METHOD AND APPARATUS

(71) Applicant: SOROOSH MAHMOODI, TEHRAN (IR)

(72) Inventor: SOROOSH MAHMOODI, TEHRAN (IR)

(21) Appl. No.: 16/590,395

(22) Filed: Oct. 2, 2019

(51) Int. Cl. B05D 1/00; B05C 5/02

(52) U.S. Cl. CPC B05D 1/005; B05C 5/0287

(57) ABSTRACT

A modified technology of spin coating which is named Two-Axis spin coating is disclosed. The innovative Two-Axis spin coating apparatus is a rotary device that spins the substrate horizontally the same as conventional spin coaters while the whole horizontal spinning system can be rotated vertically. The vertical rotation of the substrate generates a vertical centrifugal force perpendicular to the surface of the substrate which allows the coating face with an elevated artificial gravity acceleration. The elevation of gravity acceleration adjusts and normalizes the local high and low surface tension stresses on the surface of the coated film. This elevation of gravity also increases the weight of coating elements artificially and obliges the wavy surface convex regions to flow toward the concave areas. The elevation of gravity also obliges the lighter probable air bubbles inside the layer, immediately before the coating surface skinning process, move toward the surface and drain out from the layer. The invention provides a method to level the layer's edge beads, level the coated surface, drain out probable micro sized air bubbles inside the layer and form denser film simultaneously.

### REFERENCES CITED

### U.S. Patent Documents

| | | |
|---|---|---|
| 3,858,547 | January 1975 | Bergfelt |
| 4,113,492 | September 1978 | Sato et al. |
| 4,124,411 | November 1978 | Meuleman et al |
| 4,393,807 | July 1983 | Fujimura et al. |
| 4,528,934 | July 1985 | Nakayama |
| 4,822,639 | April 1989 | Fuji et al. |
| 5,095,848 | March 1992 | Ikeno et al. |
| 5,766,354 | January 1998 | Ohmori et al. |
| 6,241,825 | January 2001 | Wytman |
| 6,454,864 | September 2002 | Wytman |
| 8,652,571 | February 2014 | Nakazawa |
| 8,863,684 | October 2014 | Stangle et al. |
| 9,768,014 | October 2014 | Park et al. |

### OTHER PUBLICATIONS

1—Soroosh Mahmoodi, August 2018, U.S. Provisional Patent Application, 62/713,561, TWO-DIMENSIONAL (2D) SPIN COATING APPARATUS AND TWO-AXIS SPIN COATING-METHOD TO FORM SURFACE LEVEL FILMS WITHOUT EDGE BEAD AND CONDENSED LAYERS WITHOUT AIR BUBBLE SIMULTANEOUSLY.
2—Soroosh Mahmoodi, et al., Two-dimensional spin coating with a vertical centrifugal force and the effect of artificial gravity on surface leveling. Journal of Coatings Technology and Research, 13(6), 1123-1137(2016)
3—Soroosh Mahmoodi, et al., Two-dimensional spin coating technology and the effect of artificial gravity on film's air-bubbling. Microsystem Technologies, 23(5), 1585-1594 (2017)
4—Bornside et al., “Spin coating: One-dimensional model,” Journal of Applied Physics, 66(11):5185-5193, Dec. 1, 1989
5—Bornside et al., “On the Modeling of Spin Coating,” Journal of Imaging Technology, vol. 13, 4:122-130, August 1987
6—Clarkson et al., “Visualization of Flow Instabilities on a Rotating Disk,” AIAA Journal, vol. 18, 1541-1543, December 1980
7—Daughton et al., “An Investigation of the Thickness Variation of Spun-on Thin Films Commonly Associated with the Semiconductor Industry,” Journal of Electrochem. Soc, vol. 129, 1:173-179, January 1982
8—Ellison, “Mass Transfer to a Rotating Disk,” Journal of Electrochem. Soc., 18:68-72, January 1971
9—Emslie et al., “Flow of a Viscous Liquid on a Rotating Disk,” Journal of Applied Physics, vol. 29, 5:858-862, May 1958
10—Fedorov et al., “Transitional Flow Conditions on a Rotating Disk,” Journal of Engineering Physics, vol. 31, 1448-1453, December 1976
11—Flack et al., “A Mathematical Model for Spin Coating of Polymer Resists,” Journal of Applied Physics, vol. 56, 4:1199-1206, August 1984
12—Kobayashi et al., “Spiral Vortices in Boundary Layer Transition Regime on a Rotating Disk,” ACTA Mechanica, 35:71-82, 1980.
13—Kohama et al., “Study on Boundary Layer Transition of a Rotating Disk,” Acta Mechanica, 50:193-199, 1984.
14—Kreith et al., “Heat and Mass Transfer from a Rotating Disk,” Journal of Heat Transfer, 81:95-105, May 1959.
15—Lai et al., “An Investigation of Spin Coating of Electron Resists,” Polymer Engineering and Science, vol. 19, 15:1117-1121, November 1979.
16—Malik et al., “Instability and Transition in Rotating Disk Flow,” AIAA Journal, vol. 19, 9:1131-1138, September 1981.
17—Meyerhofer, “Characteristics of Resist Films Produced by Spinning,” Journal of Applied Physics, vol. 49, 7:3993-3997, July 1978.
18—Smith, “Exploratory Investigation of Laminar-Boundary-Layer Oscillations on a Rotating Disk, Technical Note No. 1227,” National Advisory Committee for Aeronautics, 1-15, May 1947.
19—Sparrow et al., “Mass Transfer, Flow, and Heat Transfer about a Rotating Disk,” Journal of Heat Transfer, 82:294-302, November 1960.
20—Stuart et al., “On the Stability of Three-Dimensional Boundary Layers with Application to the Flow Due to a Rotating Disk,” Price 17s. 6d., vol. 248, 20-199, Jul. 14, 1955.
21—Sukanek, “Spin Coating,” Journal of Imaging Technology, vol. 11, 4:184-190, August 1985.
22—Szeri et al., “Short Communication Stability of Flow Over a Rotating Disk,” International Journal for Numerical Methods in Fluids, vol. 4, 989-996, 1984.
23—Wilkinson et al., “Stability Experiments in the Flow over a Rotating Disk,” AIAA Journal, vol. 23, 4:588-595, April 1985.

### BACKGROUND OF THE INVENTION

### (1) Field of the Invention

The invention is generally related to the semiconductor industries where the coating of photoresist or other industrial sol-gels are principally performed. More particularly, the invention is related to a method for leveling the surface of coated films and achieving uniform thickness all over the coated substrate. The invention also related to a modified spin coating method to drain out the probable inner layer air bubbles and form denser films.

### (2) Background of the Related Art

Coating, photolithography, and etching, generally, are three main processes within the semiconductor industries. The coating is one of the most important processes which influence the quality of the fine etched patterns such as those required in the production of semiconductor devices.

Bare silicon wafers, after pretreatment, would be coated by a photoresist or other industrial coatings. The coated photoresist layer is cross-linked by an UV light radiation of an exposure device. The radiation passes a reticle mask and burns the designed features of the mask through the photoresist's film. The exposed or non-exposed patterns, depending on the negativity or positivity of photoresist, can be removed by a chemical developer to etch the exposed patterns. These patterns on the surface of the coated wafer represent a two-dimensional layout of the desired structure. It is therefore important to form a uniform photoresist layer, while at the same time ensuring that the generation of air bubbles inside the layer is minimized. Minimization of bubbles inside the coated film increases the resolution of the exposed patterns, as well as increases the pattern's density.

Spin coating technology is a famous low-cost industrial method that has been used for many years to form thick and thin films. The coating material is deposited at the center of a substrate which can be rotated by the spinning machine fast enough to spread the solution radially all over the substrate. The conventional spin-coated layers over topography are determined by the reaction of the fluid elements under various types of forces such as horizontal centrifuge force, viscous forces, capillary force, surface tension forces, and coating shrinkage.

There are several types of common spin coating defects such as uneven surface leveling, inner layer air bubbling, and edge beading which are considered especially for high viscous coatings. As the size of the topography's feature gets micron size, creating a method to flatten out the applied coatings to achieve surface-level films became an important target. Uneven surface leveling defect may happen due to fast evaporation of the solution's solvents and shortage of gravity acceleration which does not allow the coating's surface tension to level the surface of film properly. Uneven surface leveling is more undesirable while multilayer of coatings is considered.

Ikeno; Masahiko on March 1992 presented an invention with 5,095,848 US patent number which discloses a modified technology of spin coating which includes the steps of applying a coating material on the surface of a substrate, rotating the substrate on a chuck about a first axis, and revolving the substrate about a second axis while tilting the substrate towards the second axis by a mechanism. He also presented a novel technique as the housing and coating chamber. The rotating step spreads the coating material over the surface of the substrate, and the step of revolving while tilting the substrate smoothens the surface of the coating material with uniform thickness. Two-Axis spin coating innovation here is very similar to his innovation but there are some technical differences which are mentioned in the following. Both axis of rotating and revolving, in his invention, are parallel to each other, and then the first axis of rotation tilt toward the revolving axis. However here, in the Two-Axis spin coating invention, both axes of horizontal and vertical rotations permanently are perpendicular to each other and there are not any tilt mechanisms within the horizontal rotation axis. Ikeno's invention also presented a revolving axis that permanently is perpendicular to the ground wherein the Two-Axis spin coating invention the axis of the vertical rotation permanently is parallel to the ground. If the revolution within Ikeno's invention performs without the rotating of the substrate about the first axis while the chuck is being tilted, the coated film would be ruptured due to the downward earth's gravity. However, in the Two-Axis spin coating innovation which is disclosed here, no rupture threatens the film even if the horizontal spinning is stopped. Both horizontal and vertical rotations' axis are permanently perpendicular to each other within the Two-Axis spin coating innovation.

The Micro-Sized air bubbles inside the coated films might be created during the coating preparation, the fast-horizontal spinning of a substrate, or fast evaporation of coating's solvents. The probability of this defect rises where the surface of the coating evaporates quickly enough before bubble releasing which is known as the surface skinning process. Many High-Tech Labs lay the coated layers inside a vacuum chamber to suck out the probable air bubbles which are time-consuming and costly. There is also previous art that disclosed a method to drain out the probable air bubbles of films by vibrating the coating liquid. U.S. Pat. No. 4,633,804, issued to Arii in January 1987 discloses a treatment method of a semiconductor wafer in which a generated supersonic power vibrates the dispensed liquid material on the wafer. It proposes that the small sizes of air bubbles are effectively released from the surface of the liquid film.

Another problem associated with conventional spin coating methods is photoresist beading at the outer edge of the spinning wafer. Edge beading is the most common defect in which the thickness of the coated layer at the center of the substrate is thinner than the edge. During the spinning of the substrate, the horizontal centrifuge force of spinning pushes the coating materials toward the edge of the substrate and forms it thicker than the center. It is also believed that surface tension and adhesion of the photoresist give a rise to this thickness and form a “zone of increased thickness” at the edge. This beading can typically contribute to a significant loss in functional devices that lie at and near the outer edge of the wafer. Many industries suggested dissolving the peripheral of the film with solvents and then a sudden rise of the horizontal spinning speed can generate a huge horizontal centrifuge force on the coating elements to spread out the thicker edges. U.S. Pat. No. 4,113,492, issued to Sato et al. on Sep. 12, 1978, teaches simultaneously applying coating solvent to a peripheral portion of the underside of a wafer in a spin coating apparatus while depositing the coating on the topside. Whereas, U.S. Pat. No. 4,518,678, issued May 21, 1985 to Allen discloses repeatedly contacting a peripheral portion of the underside of a slowly spinning wafer with coating solvent and spinning the wafer at successively higher speeds to remove the dissolved fat edges. Other scientists and innovators suggest applying different types of chemical solvents by various methods and innovative devices at the peripheral of a coated wafer to wash and remove the thicker edge. U.S. Pat. No. 4,510,176 issued Apr. 9, 1985, to Cuthbert et al., discloses a method to apply a resist solvent to the periphery of the top surface of a spinning wafer to remove the thicker edge. U.S. Pat. No. 4,685,975 issued to Kottman et al. on Aug. 11, 1987, teaches removing a coating from the edge and a peripheral portion of the back surface of a wafer by applying solvent to a peripheral area of the rear surface of a spinning wafer. U.S. Pat. No. 4,732,785 issued to Brewer on Mar. 22, 1988, discloses a method by applying a pulsed or repeating of a solvent on the edge of the coated substrate, a backwash step of constant rotational speed, and deceleration over time can provide a means of smoothing and gradual cutting back of the spun-on film edge. U.S. Pat. No. 5,279,926 issued Jan. 12, 1994, to Chandler et al., utilizes the application of a photoresist solvent to a peripheral area of the bottom surface of a spinning wafer to remove the photoresist coating inadvertently deposited in that area during its deposition on the upper surface. U.S. Pat. No. 6,524,775 issued to Oberlander on Feb. 25, 2003, discloses a method for treating a photoresist composition film disposed on a surface which method comprises contacting the photoresist composition with a solvent mixture to produce a substantially uniform film thickness of the photoresist composition across the surface. U.S. Pat. No. 6,565,920 issued to Endisch on May 20, 2003, discloses a method that expands a fluid through a nozzle to form a cryogenic aerosol stream and directs the cryogenic aerosol stream against the film in a region of the surface adjacent to an edge of the surface as the substrate spins. U.S. Pat. No. 8,641,831 issued to Benson on Feb. 4, 2014, discloses a method and an apparatus for removing the edge bead from a substrate by applying an impinging stream of a medium that is not a solvent for the material to be removed. The medium is applied to the periphery of the substrate with sufficient force to remove the material. U.S. Pat. No. 9,548,225 issued to Liu, et al. on Jan. 17, 2017, discloses an edge bead removal apparatus that includes a clamping unit configured to clamp a cylindrical reticle and cause the cylindrical reticle to incline with a pre-determined angle and to rotate around a central axis. The edge bead removal apparatus also includes an edge bead removal solvent nozzle configured to spray an edge bead removal solvent to remove edge beads on both edges of the cylindrical reticle. U.S. Pat. No. 9,908,201 issued to Chang, et al on Mar. 6, 2018, discloses Systems and methods to remove edge beads where a laser beam along a predetermined beam path is projected on an edge portion of a wafer for edge bead removal.

The effect of gravity due to the earth's gravity shortage compared with the pressure gradient, kinematic viscosity of coatings, and other exerted forces of the conventional spin coating was ignored. An elevated gravity acceleration can be a dominant factor to level the surface, drain out the inner layer bubbles, and level the edge beads. This innovation discloses an apparatus that looks like the conventional spin coating devices can spread the coatings on the surface of a wafer while the gravity acceleration artificially can be elevated.

### SUMMARY OF THE INVENTION

The present invention discloses a method and an apparatus to spin coating materials by two-axis (horizontal and vertical) rotations over the surface of wafers which I called it Two-Axis spin coating method and apparatus. The present invention can be implemented in numerous ways, including as a process, an apparatus, a system, a device, or a method.

In one embodiment, the present invention is started by depositing a coating material on a front surface of a substrate. A horizontal rotation of the substrate which largely resembles the conventional spin coating method spread the coating materials on the substrate surface where the invention utilizes a vertical rotation of the whole horizontal rotating system that the angle between the horizontal and vertical axes is 90° degree. This vertical rotation generates an elevated centrifugal acceleration. The outward exerted centrifuge acceleration perpendicular to the element of coating on the surface of the substrate can be considered as an elevated artificial gravity acceleration constantly in the downward direction. It means, the seated mass on the surface of a coated substrate face with a controllable artificial gravity acceleration while the vertical rotation is performing. The values of artificial gravity acceleration (e.g., 500±1 g) can be controlled by increasing or decreasing the speed of vertical rotation. A flowchart of the Two-Axis spin coating method is drawn and shown in FIG. 8. The flow chart largely resembles the conventional spin coating procedure except for the fourth step, which is called the vertical centrifugal force. The manufactured innovative apparatus is shown in FIG. 9.

The elevated artificial gravity acceleration adjusts and normalizes the local high and low surface tension stresses on the surface of films. The coating particles become heavier than the normal condition. This elevated heaviness overcomes coating viscosity and obliges the convex regions to flow toward the concave areas to form surface-level films. This gravity elevation increases the reduction of surface amplitude irregularities and forms level films. A schematic of this effect is shown in FIG. 5. The decay time of surface leveling decreases while the values of artificial gravity acceleration are increased. Some experiments were performed using the manufactured innovated apparatus. Photoresist AZP4620 was chosen as the coating material and polished bare silicon wafers as the coating substrate. FIG. 10 shows Cross-Section SEM images of coated photoresist AZP4620 using the Two-Axis spin coating method. The SEM images show a fantastic surface-level condensed film without any bubbles.

Furthermore, increasing the weight of coating particles also obliges the much lighter air bubbles immediately, before the surface skinning process, moves toward the coating's surface and be released. The velocity of Micro-Sized Air-Bubbles' motion toward the coating surface can be increased by increasing the values of elevated artificial gravity acceleration. This increase also creates a huge decrease in the decay time of the Air-Bubbling release. The drain out of bubbles causes to form denser layers without any porosity or rupture. A schematic of this effect is shown in FIG. 6. Some other experiments by the innovated device using photoresist SU8-3050 are also performed. FIG. 11 shows a Cross-Section SEM image of a conventional spin-coated film whereas FIG. 12 shows a Cross-Section SEM image of a Two-Axis spin-coated film. A comparison between both SEM images shows a condensed surface level layer of photoresist SU8-3050 using the Two-Axis spin coating apparatus. FIG. 13 shows a surface SEM image of the conventional spin-coated film. FIG. 14 shows a surface SEM image of a Two-Axis spin-coated layer which shows denser particles of photoresist on the surface of Two-Axis spin-coated film. Furthermore, the elevated artificial gravity acceleration also obliges the main significant parts of the thicker film's peripheral around the coated substrate's edge, before complete drying, flow out and some other remained part of the thicker peripheral flow toward the substrate's center and form the uniform thickness layer. A schematic of this effect is shown in FIG. 7. Some experiments were also performed using SU8-3050 where FIG. 15 shows a Cross-Section SEM image of a conventional spin-coated wafer and FIG. 16 shows the Two-Axis spin-coated thin film which shows an accurate uniform thickness equal to 42.57 μm. The formation of thin films with uniform thickness is the most desired phenomenon in the coating of big-sized wafers in semiconductor industries.

Advantageously, the elevation of artificial gravity acceleration by the innovative Two-Axis spin coating apparatus causes to form condensed layers without bubbling and surface-level films without edge beading simultaneously.

### BRIEF DESCRIPTION OF THE DRAWINGS

FIG. 1 shows an X-direction view of the Two-Axis spin coating device according to an embodiment of the invention with its different parts numbered and marked.

FIG. 2 shows a perspective view of the Two-Axis spin coating device according to an embodiment of the invention with its different parts numbered and marked.

FIG. 3 shows a perspective view of the Two-Axis spin coating device according to an embodiment of the invention which shows a schematic representation of the vertical and horizontal rotations of the device.

FIG. 4 shows a closer perspective view of the horizontal rotation system and parts of the Two-Axis spin coating device according to the embodiment of the invention.

FIG. 5 shows a schematic effect of elevated artificial gravity acceleration on film's surface leveling using the Two-Axis spin coating method according to the embodiment of the invention.

FIG. 6 shows a schematic effect of elevated artificial gravity acceleration on film's air bubbling using the Two-Axis spin coating method according to the embodiment of the invention.

FIG. 7 shows a schematic effect of elevated artificial gravity acceleration on film's edge beading using the Two-Axis spin coating method according to the embodiment of the invention.

FIG. 8 shows a flow chart process of the Two-Axis spin coating method according to the embodiment of the present invention.

FIG. 9 shows the manufactured innovated device which is named Two-Axis spin coating apparatus.

FIG. 10 shows a Cross-Section SEM Image of a photoresist (AZP4620) layer coated by the Two-Axis spin coating method.

FIG. 11 shows a Cross-Section SEM Image of a photoresist (SU8-3050) layer coated by the conventional spin coating method.

FIG. 12 shows a Cross-Section SEM Image of a photoresist (SU8-3050) layer coated by the Two-Axis spin coating method.

FIG. 13 shows a surface SEM Image of a photoresist (SU8-3050) layer coated by the conventional spin coating method.

FIG. 14 shows a surface SEM Image of a photoresist (SU8-3050) layer coated by the Two-Axis spin coating method.

FIG. 15 shows a Cross-Section SEM Image of a photoresist (SU8-3050) layer coated by the conventional spin coating method.

FIG. 16 shows a Cross-Section SEM Image of a photoresist (SU8-3050) layer coated by the Two-Axis spin coating method.

### DETAILED DESCRIPTION OF THE INVENTION

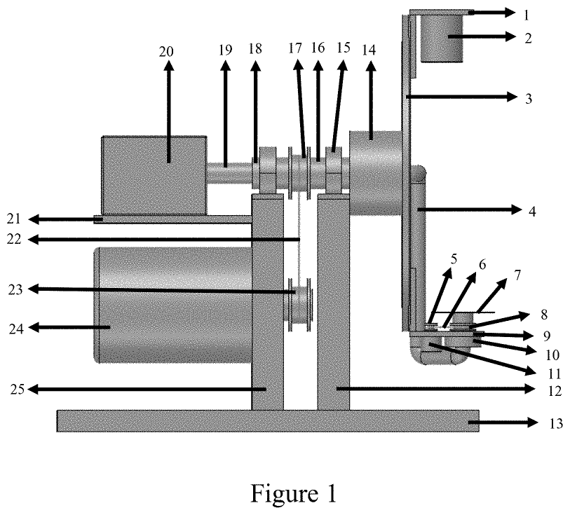

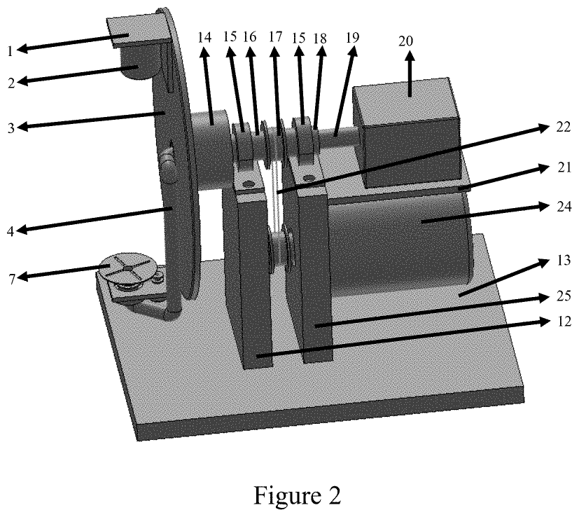

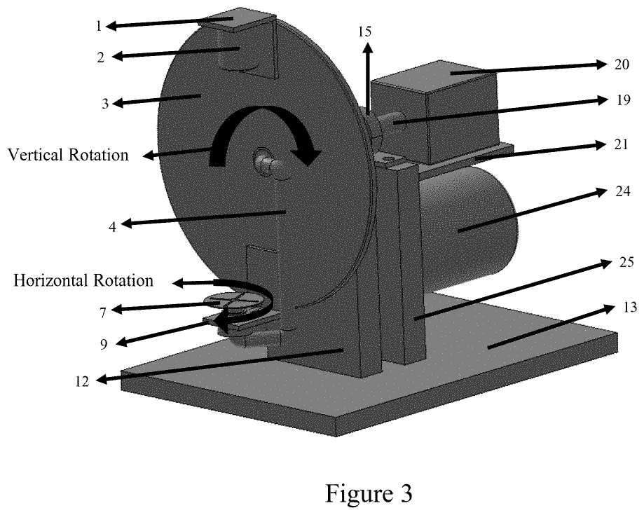

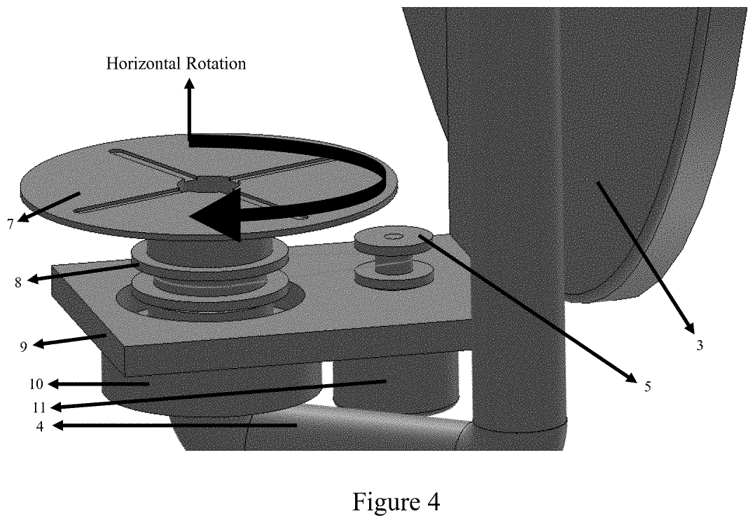

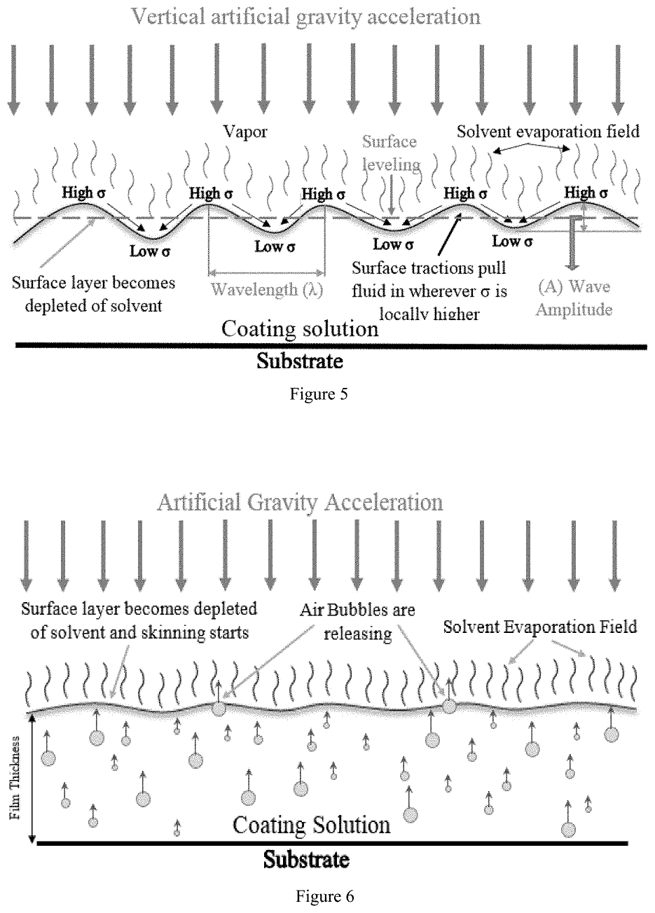

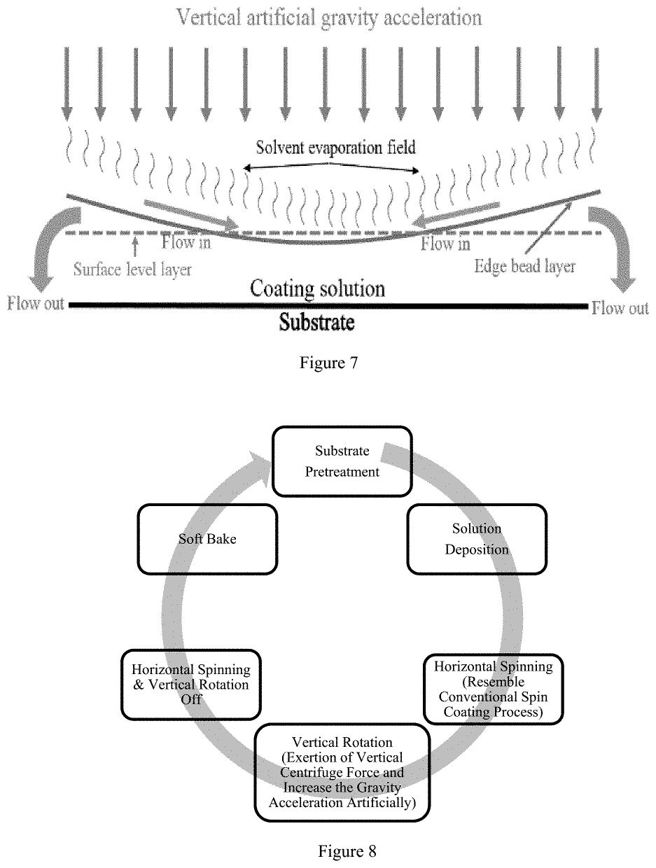

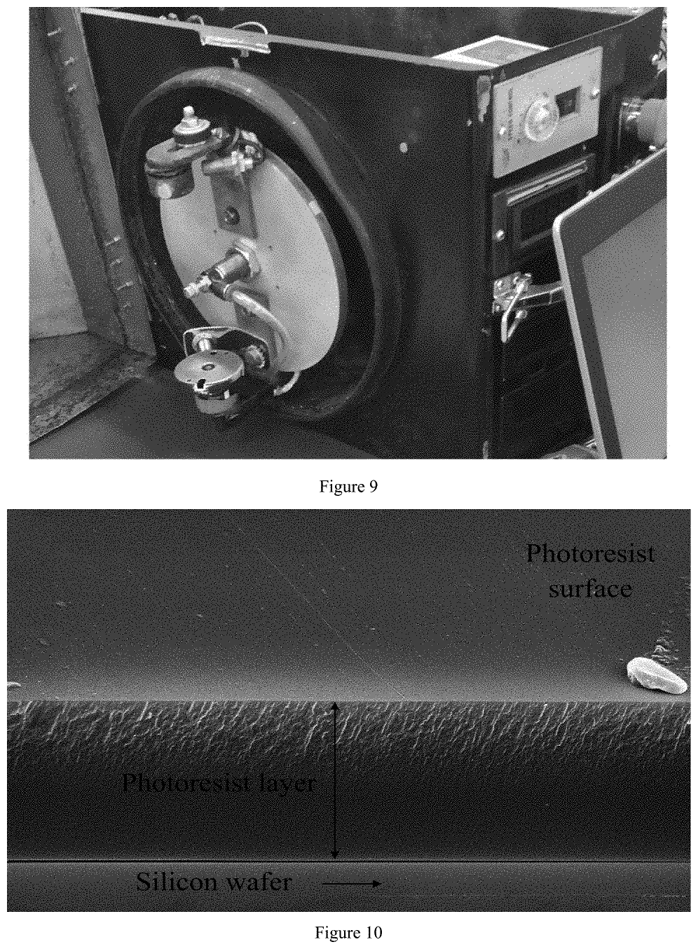

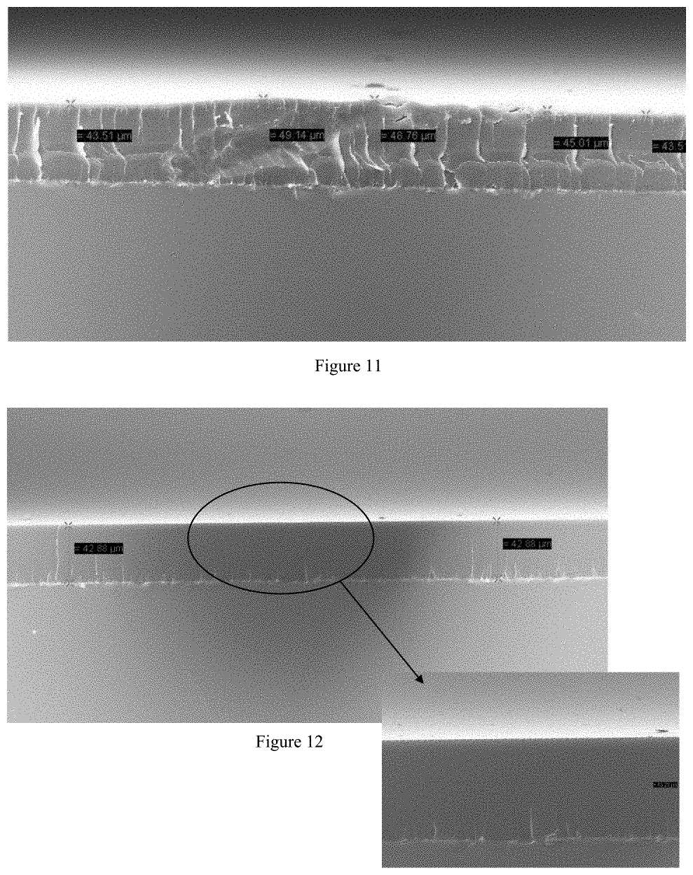

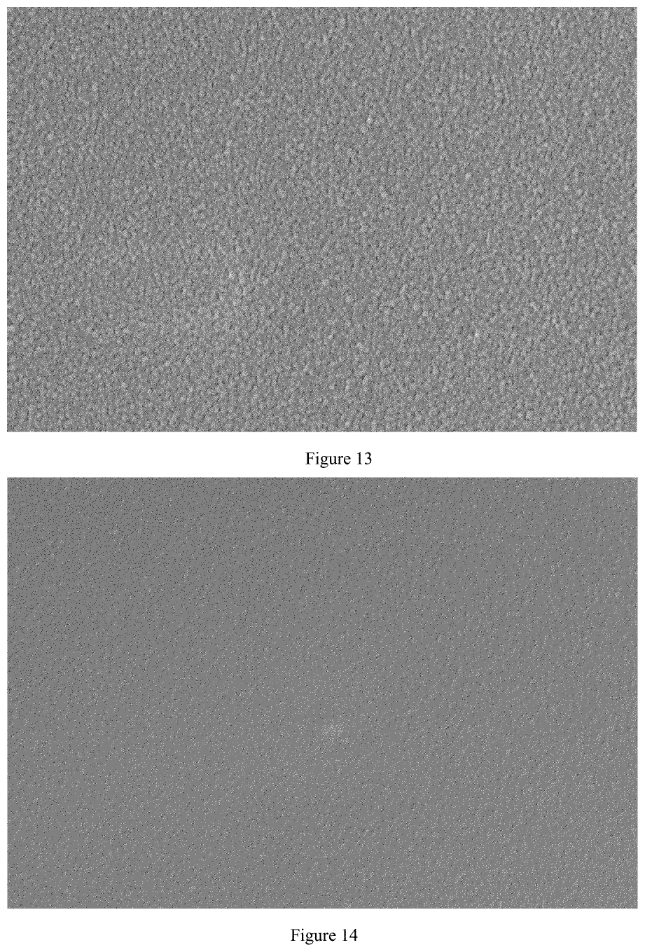

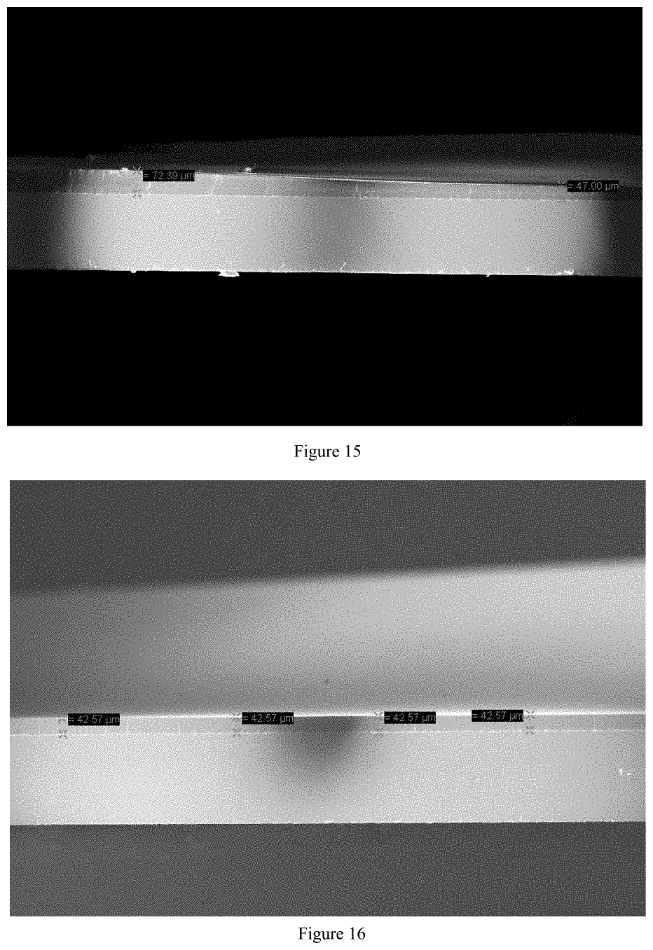

Referring to FIGS. 1, 2, 3, and 4, in accordance with an embodiment of the innovated present apparatus, various sizes and different types of substrates and wafers can settle on a horizontal spinning chuck 7. An electric motor 11 is adjusted on a bracket holder 9 to supply the rotation of the horizontal spinning chuck 7. The rotation power of the motor 11 can be transmitted to the spinning chuck 7 by a belt 6. The belt 6 transmits the rotation of a pulley 5 which is connected to the motor 11 to a pulley 8 which is connected to the spinning chuck 7. The horizontal spinning chuck system 7 is connected to the bracket holder 9 by a bearing and bearing holder 10. The bracket holder 9 is connected to a vertical rotating disk 3.

The substrates can be sucked to be held on the horizontal spinning chuck 7 by an air vacuum pump 20. The vacuumed air generated by the vacuum pump 20 can be passed through a vacuum pipe 19, a bearing and bearing holder 18, a vacuum air channel through the main shaft 16, a vacuum pipe 4, the bearing and bearing holder 10, and an air channel in the center of the horizontal spinning chuck 7. One head of the vacuum pipe 4 is connected to the bearing holder 10 and the other head is connected to the main shaft 16. There is an air channel along the longitudinal of the main shaft 16 which the generated vacuumed air by the vacuum pump 20 can be passed from the vacuum pipe 19 to the vacuum pipe 4. The bearing and bearing holder 18 connect the vacuum pipe 19 to the main shaft 16. The bearing and bearing holder 18 prevent the rotation of vacuum pipe 19 while the main shaft 16 is rotating.

The main shaft 16 can be rotated by an electric motor 24. A pulley 23 and a pulley 17 are connected to the electric motor 24 and the main shaft 16 accordingly. The pulley 23 transmits rotation power of the electric motor 24 to the pulley 17 and subsequently to the main shaft 16 by a power transmission belt 22. The main shaft 16 rotates and holds the vertical rotating disk 3 by two bearings and bearing holders 15 and 18. The bearings and bearing holders 15 and 18 let the main shaft 16 be rotated and hold the rotating disk 3 on two pedestals 12 and 25. The pedestals 12 and 25 connect the main shaft 16 and accordingly vertical rotating disk 3 to a base plate 13. The electric motor 24 is adjusted on the pedestal 25. The vacuum pump 20 is also adjusted on the pedestal 25 by a base plate 21.

To balance the mass rotation of the vertical rotating disk 3, a balancing mass 2 is adjusted on the vertical rotating disk 3 at the reverse side of the horizontal rotating components. The balancing mass 2 is connected to the vertical rotating disk 3 by a bracket holder 1. The mass of balancing mass 2 is evaluated in such a way to be equal to the horizontal rotating components including the electric motor 11, the bearing and the bearing holder 10, the both pulleys 5 and 8, the spinning chuck 7, the power transmission belt 6, and the vacuum pipe 4. This action to balance the mass objects on both sides of the vertical rotating disk 3 will prevent the device from vibrating at high vertical rotation speeds.

It is not possible to transmit electric power to electric motor 11 through wires simultaneously while the vertical rotating disk 3 is rotating. Therefore, for this electric power transmission, the innovative device needs a rotational power distributer to deliver the electric power to the components such as the electric motor 11 or any other attach equipment or sensors. The required electricity power of the DC electric motor 11 can be transmitted by a rotational power distributor 14. The rotational power distributor 14 can also transmit other probable required electricity power such as the power of sensors or other electric components into the vertical rotating system, and vice versa receive signals from those components and transmit them out while rotating the vertical rotating disk 3.

The innovative apparatus is designed and manufactured in such a way that the rotation speed of both the horizontal and vertical rotations can be controlled simultaneously. The horizontal rotation acts like the conventional spin coaters to spread the coating over the substrate and the vertical rotation generates the centrifuge acceleration and accordingly generates the artificial gravity acceleration perpendicular to the substrate. This controllable elevated artificial gravity acceleration on the elements of coating is the invention within the mentioned apparatus.

What is claimed is:

1. A method or technology using Two-Axis spin coating innovation or Two-Axis spin coating innovated apparatus to form surface level thin and thick micrometer layers without edge beading and condensed film without air bubbling simultaneously comprising:
(a) Adjusting the horizontal spinning chuck of the innovative apparatus so that the surface of the spinning horizontal chuck is parallel to the ground.
(b) Placing a circular or rectangular substrate or any other shape in the center of the horizontal spinning chuck.
(c) Sucking the substrate located in the center of the horizontal rotating chuck by turning on a vacuum pump.
(d) Dispensing enough amount of a desired coating material over the top of the said sucked substrate in the center or near the center of the said horizontal spinning chuck.
(e) Adjusting a horizontal rotational speed, acceleration rates, and rotation time of the said horizontal rotation which has been pre-determined.
(f) Adjusting a vertical rotational velocity, rotational acceleration, and their duration for the vertical rotating of the entire said horizontal rotation system, in which the angle between the said vertical and horizontal rotation axis is 90 degrees.
(g) Spinning the horizontal spinning chuck with the said pre-set values that will spread the deposited coating to the entire surface of said substrate.
(h) Starting said vertical rotation with said pre-set values after a predetermined time has elapsed since the start of said horizontal rotation.
(i) Continuing the both said horizontal and vertical rotations simultaneously for a predetermined period time where the said vertical rotation would generate a centrifugal force perpendicular to the surface of said substrate.
(j) Holding the coated layer under the condition of elevated gravity acceleration which is created by the said centrifugal force for a predetermined duration of time. The surface of coated layer faces an airflow which is generated by the said vertical rotation. The said airflow while passing through the surface of the coated layer, the solvents of the coating are evaporated, and the layer becomes completely or partially dry. The said complete or partial drying under the effect of the said elevated gravity acceleration avoids the undesired spring back effect of the coating such as the edge beading or the wavy surface leveling.
(k) Spinning off the said vertical rotation and consequently spinning off the said horizontal rotation of the substrate.
(l) Stopping the said vertical rotation so that the surface of the said horizontal spinning chuck is held parallel to the ground.
(m) Turning the said vacuum pump off and removing the said substrate from the said horizontal spinning chuck and preparing for the next processes.

2. A method or technology according to claim 1, wherein said coating materials are included various types of industrial and medical coatings such as photoresists, metallic, Non-Metallic, polymeric, organic, inorganic, and any industrial coatings useful in micro and Nanofabrication industries and not unlimited to any unspoken coatings.

3. A method or technology for coating micrometer and nanometer layers in which the rotation axis of the both said horizontal and vertical rotations are perpendicular to each other and the angle between them is 90 degrees comprising:
(I) Coating micrometer and nanometer layers using the said vertical rotation perpendicular to said spinning chuck, a vertical centrifugal force perpendicular to the said substrate's surface is generated.
(II) Coating micrometer and nanometer layers in which the said vertical centrifugal force perpendicular to the said horizontal spinning chuck artificially increase the gravitational acceleration.
(III) Coating micrometer and nanometer layers which the said horizontal and the said vertical rotations can be performed independently or simultaneously.

1. A method or technology using Two-Axis spin coating innovation or Two-Axis spin coating innovated apparatus to form surface level thin and thick micrometer layers without edge beading and condensed film without air bubbling simultaneously comprising:
(a) Adjusting the horizontal spinning chuck of the innovative apparatus so that the surface of the spinning horizontal chuck is parallel to the ground.
(b) Placing a circular or rectangular substrate or any other shape in the center of the horizontal spinning chuck.
(c) Sucking the substrate located in the center of the horizontal rotating chuck by turning on a vacuum pump.
(d) Dispensing enough amount of a desired coating material over the top of the said sucked substrate in the center or near the center of the said horizontal spinning chuck.
(e) Adjusting a horizontal rotational speed, acceleration rates, and rotation time of the said horizontal rotation which has been pre-determined.
(f) Adjusting a vertical rotational velocity, rotational acceleration, and their duration for the vertical rotating of the entire said horizontal rotation system, in which the angle between the said vertical and horizontal rotation axis is 90 degrees.
(g) Spinning the horizontal spinning chuck with the said pre-set values that will spread the deposited coating to the entire surface of said substrate.
(h) Starting said vertical rotation with said pre-set values after a predetermined time has elapsed since the start of said horizontal rotation.
(i) Continuing the both said horizontal and vertical rotations simultaneously for a predetermined period time where the said vertical rotation would generate a centrifugal force perpendicular to the surface of said substrate.
(j) Holding the coated layer under the condition of elevated gravity acceleration which is created by the said centrifugal force for a predetermined duration of time. The surface of coated layer faces an airflow which is generated by the said vertical rotation. The said airflow while passing through the surface of the coated layer, the solvents of the coating are evaporated, and the layer becomes completely or partially dry. The said complete or partial drying under the effect of the said elevated gravity acceleration avoids the undesired spring back effect of the coating such as the edge beading or the wavy surface leveling.
(k) Spinning off the said vertical rotation and consequently spinning off the said horizontal rotation of the substrate.
(l) Stopping the said vertical rotation so that the surface of the said horizontal spinning chuck is held parallel to the ground.
(m) Turning the said vacuum pump off and removing the said substrate from the said horizontal spinning chuck and preparing for the next processes.

2. A method or technology according to claim 1, wherein said coating materials are included various types of industrial and medical coatings such as photoresists, metallic, Non-Metallic, polymeric, organic, inorganic, and any industrial coatings useful in micro and Nanofabrication industries and not unlimited to any unspoken coatings.

3. A method or technology for coating micrometer and nanometer layers in which the rotation axis of the both said horizontal and vertical rotations are perpendicular to each other and the angle between them is 90 degrees comprising:
(I) Coating micrometer and nanometer layers using the said vertical rotation perpendicular to said spinning chuck, a vertical centrifugal force perpendicular to the said substrate's surface is generated.
(II) Coating micrometer and nanometer layers in which the said vertical centrifugal force perpendicular to the said horizontal spinning chuck artificially increase the gravitational acceleration.
(III) Coating micrometer and nanometer layers which the said horizontal and the said vertical rotations can be performed independently or simultaneously.
